(19) United States
(12) Patent Application Publication
(10) Pub. No.: US 2011/0141039 A1
(43) Pub. Date: Jun. 16, 2011

(54) TOUCH PANEL

(76) Inventor: Chun-Yi Lee, Shen-zhen (CN)

(21) Appl. No.: 12/868,743

(22) Filed: Aug. 26, 2010

Related U.S. Application Data
(63) Continuation of application No. PCT/CN2010/070266, filed on Jan. 20, 2010.

(30) Foreign Application Priority Data
Dec. 15, 2009 (CN) 200910263686.2

(51) Int. Cl. G06F 3/041; H03K 17/94

(52) U.S. Cl. 345/173; 341/20

(57) ABSTRACT

A touch panel includes a substrate, and a plurality of sensing pads. The plurality of sensing pads are disposed on the substrate, wherein two adjacent sensing pads are correspondingly disposed in parallel, and each of the sensing pads includes a central part and a plurality of protrusion parts. The central part has a plurality of sides, and the plurality of protrusion parts extend outwardly from each side of the central part. The plurality of protrusion parts disposed between each side of the two adjacent sensing pads are staggeredly arranged in sequence. A gap between any two adjacent sensing pads is identical to each other.

### CROSS REFERENCE TO RELATED APPLICATIONS

This application is a continuation of International Application No. PCT/CN2010/070266 filed on Jan. 20, 2010.

### BACKGROUND OF THE INVENTION

1. Field of the Invention

The present invention relates to a touch panel, and more particularly, to a touch panel with excellent display uniformity and touch sensitivity.

2. Description of the Prior Art

A conventional touch display device is normally formed by integrating a touch panel with a display panel. The touch panel mainly includes resistive type touch panel, capacitive type touch panel, infrared type touch panel, and surface acoustic wave type touch panel, etc. Among the aforementioned types of touch panels, resistive type touch panel and capacitive type touch panel are the most common products. Due to their user-friendly interfaces, the touch display devices have gradually been prevailing in the market.

FIG. 1 is a schematic sectional top-view diagram of a conventional touch panel. Referring to FIG. 1, a touch panel 100 includes a substrate 102 and a plurality of sensing pads 110. The plurality of sensing pads 110 are disposed on the substrate 102, and a gap S exists between the two adjacent sensing pads 110. In addition, the touch panel 100, for instance, further includes a plurality of bridges (not shown) connected to the plurality of sensing pads 110, so as to transmit signals to each of the sensing pads 110. For example, when a user touches the touch panel 100 with his fingers, capacitors will be formed between the fingers and a portion of the sensing pads 110 in the region where the user touched causing signal variations.

Due to the fact that the sensing pads 110 are mounted on the substrate 102, the light transmittance of the sensing pads 110 area and that of the substrate 102 where the gap S appears between the two adjacent sensing pads 110 are different and such difference ends up causing the touch panel 100 having display mura. That is, when user looks at the touch display device including the touch panel 100, poor quality of display images would be perceived.

In view of this, Chinese Patent Application (Publication No. CN 101131492) proposes a method of improving display uniformity of touch panel's light transmittances in between sensing pads and substrate, which disposes dummy patterns between two adjacent sensing pads. Also, Chinese Patent Application (Publication No. CN 101126969) proposes a capacitive type touch panel with the polygonal-shaped sensing pad design intending to reduce the gap length between the two adjacent sensing pads. However, disposing dummy patterns between two adjacent sensing pads, as seen in CN 101131492, requires high process accuracy, and CN 101126969 cannot resolve the aforementioned display mura problem effectively because of using the polygonal-shaped sensing pads design needs large area for total gaps.

Therefore, how to improve the display uniformity of the touch panel's light transmittances is an issue to be resolved.

### SUMMARY OF THE INVENTION

The present invention provides a touch panel with good display uniformity and touch sensitivity.

The present invention provides a touch panel including a substrate and a plurality of sensing pads. The plurality of sensing pads are disposed on the substrate, wherein two adjacent sensing pads are correspondingly disposed in parallel, and each of the sensing pad includes a central part and a plurality of protrusion parts. The central part has a plurality of sides, and the plurality of protrusion parts extend outwardly from each side of the central part. The plurality of protrusion parts disposed between sides of the two adjacent sensing pads are staggeredly arranged in sequence. Gaps between any two adjacent sensing pads in normal direction are identical to each other.

In an embodiment of the present invention, the plurality of protrusion parts have the same shape.

In an embodiment of the present invention, each of the sensing pads further includes a plurality of indentation parts. The indentation parts indent inwardly from each side of the central part, and the plurality of protrusion parts and the plurality of indentation parts of each of the sensing pads are staggeredly arranged.

In an embodiment of the present invention, the plurality of protrusion parts and the plurality of indentation parts have the same shapes respectively.

In an embodiment of the present invention, the central part of each of the sensing pads is rhombus-shaped or square-shaped.

In an embodiment of the present invention, the plurality of protrusion parts of each of the sensing pads are rectangle-shaped, triangle-shaped, trapezoid-shaped or arc-shaped.

In an embodiment of the present invention, the gaps between any two adjacent sensing pads are between 30 micrometers and 50 micrometers.

In an embodiment of the present invention, the plurality of protrusion parts of each of the sensing pads are identical in number.

In an embodiment of the present invention, a material of the plurality of sensing pads includes a transparent conductive material. The transparent conductive material includes indium tin oxide or indium zinc oxide.

Based on this invention, the sensing pads of the touch panel of the present invention include a plurality of protrusion parts and a plurality of indentation parts arranged staggeredly in sequence in order to make the edges of the sensing pads saw-toothed. Accordingly, it is more unlikely to perceive the display mura due to a visual blurring effect when the user looks at the touch display device including the touch panel. Also, since the gaps between sensing area of any two adjacent sensing pads in normal direction are identical to each other, the capacitance of the touch panel of the present invention is more uniform than aforementioned prior art designs. In addition, since the protrusion parts increase the sensing area, the thickness of the sensing pad multiplied by the gap length, of the sensing pads, the touch panel of the present invention has better touch sensitivity. Moreover, the touch display device including the above touch panel has excellent display effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic sectional top-view diagram of a conventional touch panel.

FIG. 2 is a schematic sectional top-view diagram of a touch panel according to a first embodiment of the present invention.

FIG. 3 is a schematic sectional top-view diagram of a touch panel according to a second embodiment of the present invention.

FIG. 4 is a schematic sectional top-view diagram of a touch panel according to a third embodiment of the present invention.

FIG. 5 is a schematic sectional top-view diagram of a touch panel according to a fourth embodiment of the present invention.

FIG. 6A is a schematic sectional top-view diagram of the touch panel of FIG. 1, wherein more sensing pads are illustrated.

FIG. 6B is a schematic sectional top-view diagram of the touch panel of FIG. 4, wherein more sensing pads are illustrated.

FIG. 7 is a schematic diagram of a touch display device including the touch panel of the present invention.

### DETAILED DESCRIPTION

### First Embodiment

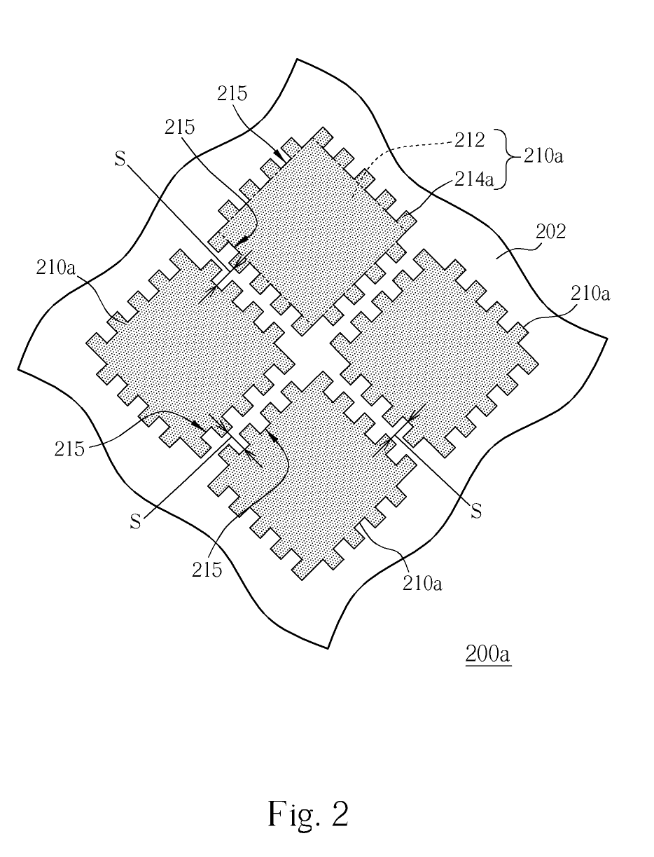

FIG. 2 is a schematic sectional top-view diagram of a touch panel according to a first embodiment of the present invention. Referring to FIG. 2, a touch panel 200a includes a substrate 202 and a plurality of sensing pads 210a. In this embodiment, the substrate 202 is a rigid transparent substrate, e.g. a glass substrate. In other embodiments, the substrate 202 may be a plastic transparent substrate or other flexible or bendable transparent substrates. The material of the sensing pads 210a can be transparent conductive material such as: indium tin oxide, indium zinc oxide or other suitable transparent conductive materials.

The plurality of sensing pads 210a are disposed on the substrate 202, wherein two adjacent sensing pads are correspondingly disposed in parallel, and each sensing pad 210a includes a central part 212 and a plurality of protrusion parts 214a. The central part 212 includes a plurality of sides 215, and the plurality of protrusion parts 214a extend outwardly from each side 215 of the central part 212. In the touch panel 200a, the central part 212 of each sensing pad 210a is rhombus-shaped or square-shaped, but not limited to this. In other embodiments, the central part 212 of each sensing pad 210a may be other suitable shapes.

In two adjacent sensing pads 210a, the plurality of protrusion parts 214a between the two sides 215, which are correspondingly arranged in parallel, are staggeredly arranged in sequence. That is, between the two sides 215 correspondingly arranged in parallel, the protrusion part 214a protruding from one side 215 faces the other side 215.

In the touch panel 200a, the protrusion parts 214a of each sensing pad 210a is identical in number, and the plurality of protrusion parts 214a have the same shape, for instance, all of the protrusion parts 214a are rectangle-shaped. The plurality of protrusion parts 214a protrude outwardly from the sides 215 of each sensing pad 210a, such that the edges of each sensing pad 210a form saw-toothed patterns. Accordingly, when looking at the touch panel 200a, the gap S observed by the user will bend along the profile of the saw-toothed edges of the sensing pads 210a, so as to produce a visual blurring effect. Therefore, in comparison with the conventional touch panel 100, it is unlikely for the user to perceive the display mura on the touch panel 200a.

Since the total sensing area of each sensing pad 210a is the sensing area of the central part 212 and the sensing area of the plurality of protrusion parts 214a, the total sensing area of the sensing pad 210a is larger than that of the conventional sensing pad. Consequently, when the user touches the touch panel 200a, the capacitance variation of the sensing pad 210a in the region of the touch panel 200a being touched is more pronounced. Namely, in comparison with the conventional touch panel 100, the touch panel 200a of the present embodiment has better touch sensitivity.

In this embodiment, the plurality of protrusion parts 214a have the same shape and area, and the gaps S between each protrusion part 214a and the corresponding side 215 in normal direction are identical to each other. That is, any two adjacent sensing pads 210a in normal direction have the gap S of identical distance. In this embodiment, the gaps S between any two adjacent sensing pads 210a in normal direction are approximately between 30 micrometers and 50 micrometers. Since the gaps S between any two adjacent sensing pads 210a in normal direction of the touch panel 200a are identical to each other, the distribution of capacitance in the touch panel 200a is unlikely to be affected by the protrusion parts 214a. Namely, the capacitance formed by each sensing pad 210a of the touch panel 200a is constant and uniform.

In addition, the touch panel 200a, for instance, further includes a plurality of bridges (not shown) for electrically connecting two adjacent sensing pads 210a, which can be implemented by different electrical connections based on different designs. For example, the touch panel 200a can be a capacitive type touch panel or a resistive type touch panel. On the other hand, the touch panel 200a can be single side touch panel design or dual sides touch panel design. The operation principle and other components of the touch panel 200a are known to those skilled in the art, and thus are not redundantly detailed.

### Second Embodiment

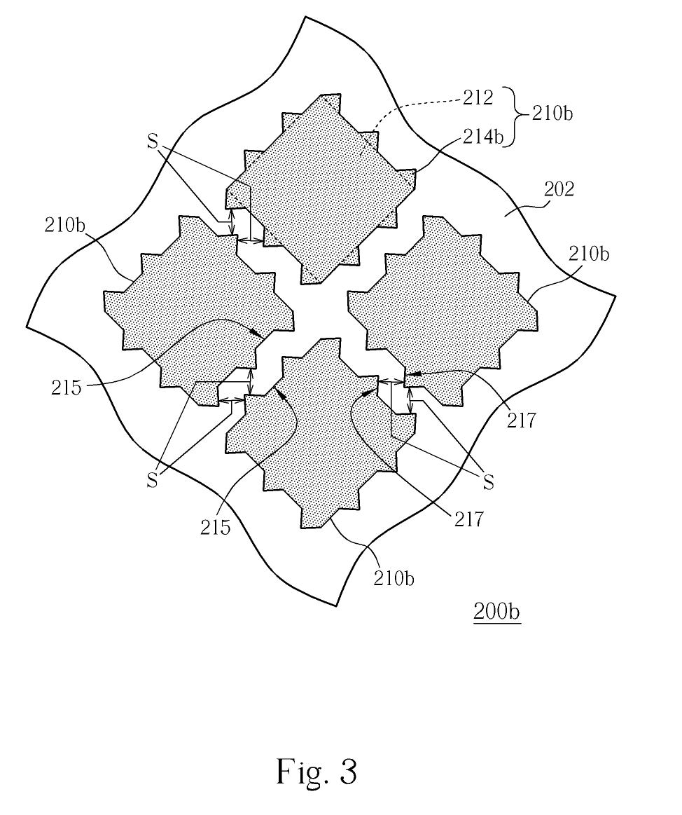

FIG. 3 is a schematic sectional top-view diagram of a touch panel according to a second embodiment of the present invention. Referring to FIG. 3, the touch panel 200b includes most of the components of the touch panel 200a, where identical components are denoted by identical numerals, and are not redundantly detailed.

The main difference between the touch panel 200b and the touch panel 200a is that, the plurality of protrusion parts 214b of each sensing pad 210b in the touch panel 200b are triangle-shaped. Also, the gap S between two adjacent sensing pads 210b in normal direction is substantially equal to the gap S between the sides 217 of two adjacent protrusion parts 214b in normal direction.

Similarly, the edges of each sensing pad 210b are saw-toothed, and the plurality of protrusion parts 214b between the two sides 215, which are correspondingly arranged in parallel, are staggeredly arranged in sequence, generating a visual blurring effect for the user. Consequently, the display mura problem of the touch panel 200b can be resolved. Furthermore, since the gaps S between any two adjacent sensing pads 210b in normal direction are identical to each other, the capacitance distribution of the touch panel 200b is uniform and constant. In addition, the protrusion parts 214b increase the sensing area of the sensing pads 210b, and therefore the touch panel 200b has better touch sensitivity.

### Third Embodiment

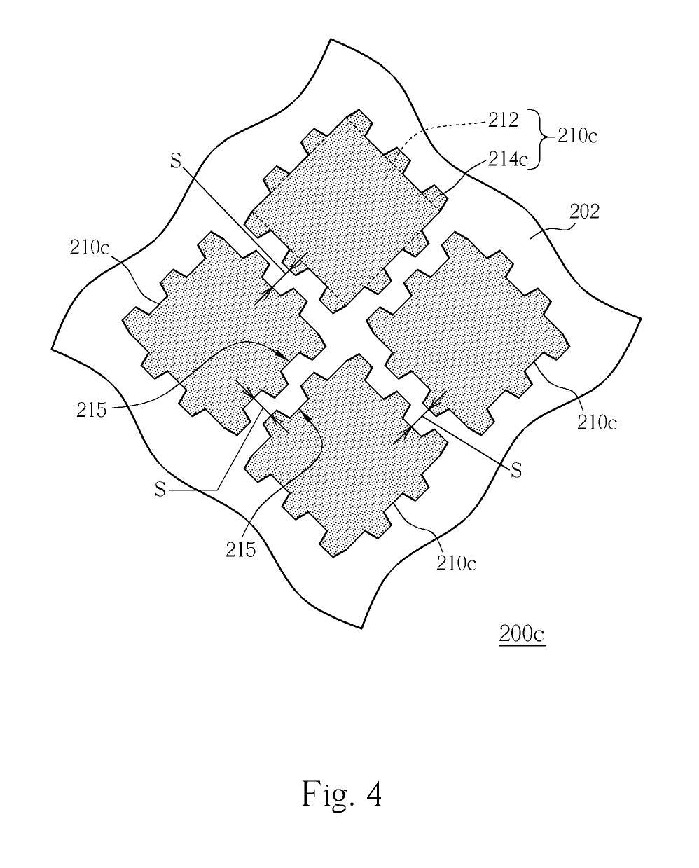

FIG. 4 is a schematic sectional top-view diagram of a touch panel according to a third embodiment of the present invention. Referring to FIG. 4, the touch panel 200c includes most of the components of the touch panel 200a, where identical components are denoted by identical numerals, and are not redundantly detailed.

The main difference between the touch panel 200c and the touch panel 200a is that, the plurality of protrusion parts 214c of each sensing pad 210c in the touch panel 200c are trapezoid-shaped. Based on the same reasons, the touch panel 200c can achieve the technical effects of the aforementioned touch panel 200a or touch panel 200b.

### Fourth Embodiment

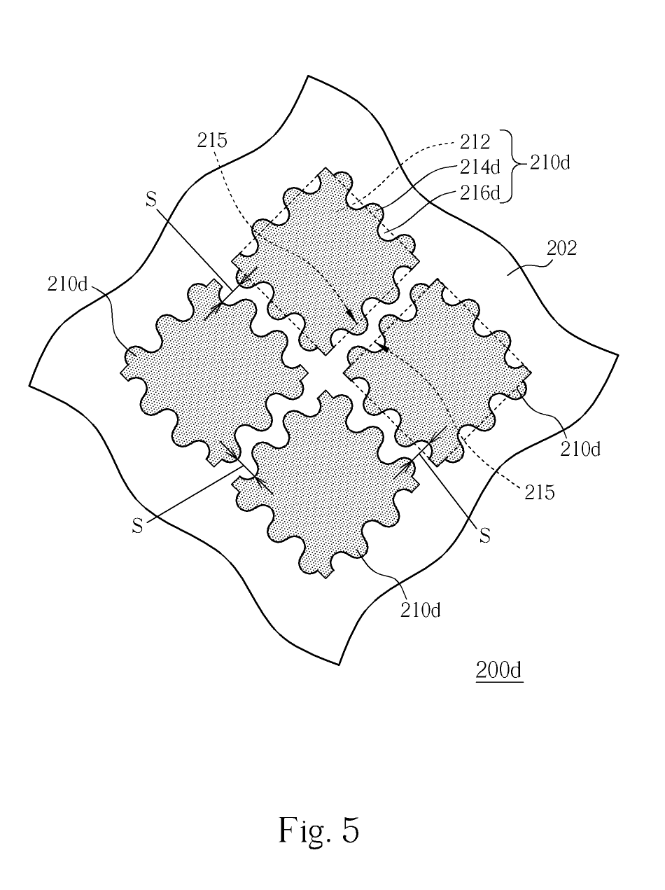

FIG. 5 is a schematic sectional top-view diagram of a touch panel according to a fourth embodiment of the present invention. Referring to FIG. 5, the touch panel 200d includes most of the components of the touch panel 200a, where identical components are denoted by identical numerals, and are not redundantly detailed.

Each of the plurality of sensing pads 210d of the touch panel 200d has a plurality of arc-shaped protrusion parts 214d. Particularly, each sensing pad 210d further includes a plurality of indentation parts 216d. The plurality of indentation parts 216d indent inwardly from the plurality of sides 215 of the central part 212, and the plurality of protrusion parts 214d and indentation parts 216d of each sensing pad 216d are staggeredly arranged in sequence. In addition, the plurality of indentation parts 216d are also arc-shaped. The above embodiment is merely an example. The shape or the number of the protrusion parts or indentation parts is not limited to this, and modification is obvious to those skilled in the art.

The sensing pads 210a, 210b, 210c and 210d of the above touch panels 200a, 200b, 200c and 200d all include a plurality of protrusion parts 214a, 214b, 214c and 214d, such that the sensing pads 210a, 210b, 210c and 210d have saw-toothed edges. The saw-tooth edges generate a visual blurring effect, which can improve the display mura problem. Also, the gaps S between any two adjacent sensing pads 210a, 210b, 210c and 210d in normal direction are identical to each other, and thus the touch panels 200a, 200b, 200c and 200d have excellent capacitance distribution. Furthermore, since the protrusion parts 214a, 214b, 214c and 214d respectively increase the area of the sensing pads 210a, 210b, 210c and 210d, the touch panels 200a, 200b, 200c and 200d have better touch sensitivity. It is to be noted that the touch panel of the present invention is easy to be fabricated, because the touch panels 200a, 200b, 200c and 200d can be fabricated with a small modification of photo mask design without altering the original manufacturing processes.

To clearly illustrate the visual blurring effect of the present invention, the conventional touch panel and the touch panel of the present invention are juxtaposed as follows in order to understand better.

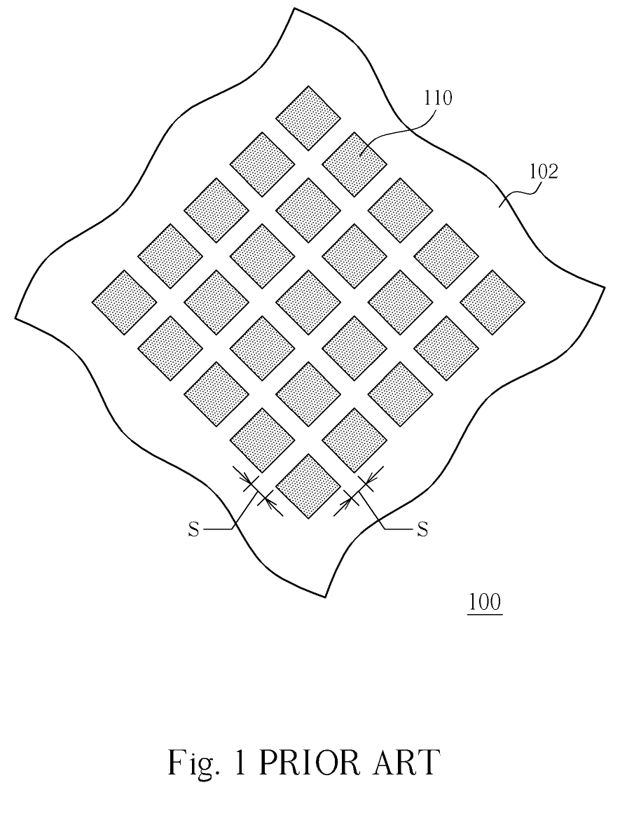

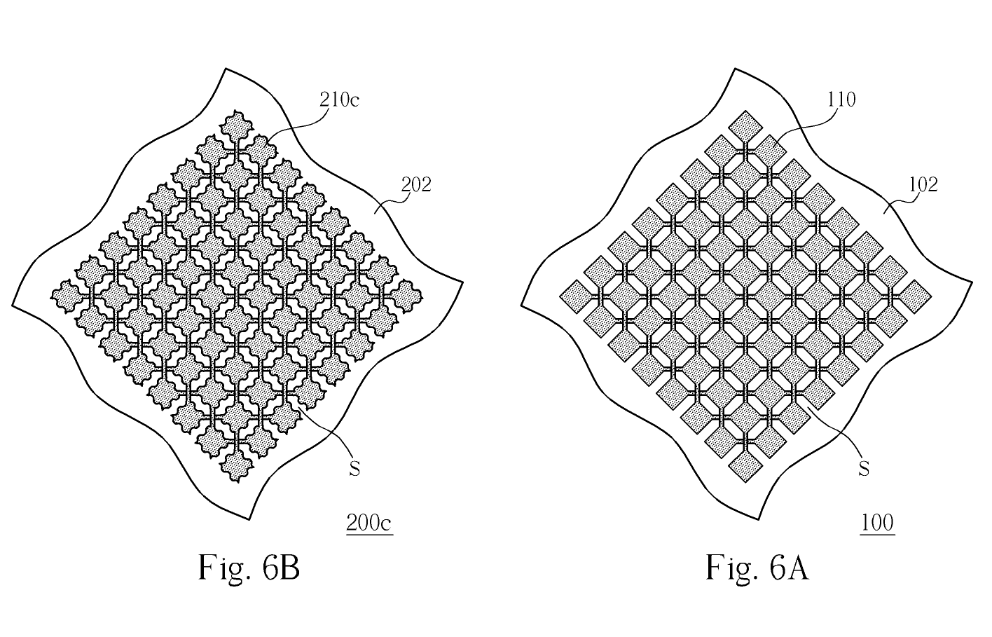

FIG. 6A is a schematic sectional top-view diagram of the touch panel of FIG. 1, wherein more sensing pads are illustrated in FIG. 6A than in FIG. 1. FIG. 6B is a schematic sectional top-view diagram of the touch panel of FIG. 4, wherein more sensing pads are illustrated in FIG. 6B than in FIG. 4. As shown in FIG. 6A and FIG. 6B, the touch panel 200c of the present invention, compared with the conventional touch panel 100, can exhibit the visual blurring effect and thus resolves the display mura problem.

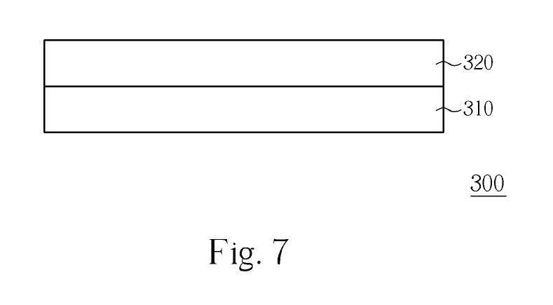

FIG. 7 is a schematic diagram of a touch display device including the touch panel of the present invention. Referring to FIG. 7, a touch display device 300 includes a display panel 310 and a touch panel 320, wherein the touch panel 320 is disposed on the display panel 310. In this embodiment, the display panel 310 is, for instance, a liquid crystal display panel, a plasma display panel or an organic electroluminescent display panel. For example, when the display panel 310 is a liquid crystal display panel, the liquid crystal display panel includes a transmissive type liquid crystal display panel, a reflective type liquid crystal display panel, a transflective type liquid crystal display panel, or other forms of liquid crystal display panels.

In the embodiment shown in FIG. 7, the touch panel 320 can be any one of the touch panels 200a, 200b, 200c and 200d illustrated in the aforementioned embodiments. Since the touch panels 200a, 200b, 200c and 200d can provide the aforementioned visual blurring effect and larger sensing area of sensing pad, the touch display device 300 has better display uniformity and touch sensitivity. Namely, the touch display device 300 has good display quality and operation characteristics.

In summary, the touch panel of the present invention includes protrusion parts staggeredly arranged in sequence, so that a visual blurring effect can be provided due to the saw-toothed edges of the sensing pads. That is, it is more unlikely for the user to perceive the display mura. Also, since the gaps between any two adjacent sensing pads in normal direction are identical to each other, the capacitance of the touch panel of the present invention is uniform and constant. In addition, since the protrusion parts increase the sensing area of the sensing pads, the touch panel of the present invention has better touch sensitivity. Moreover, the fabrication of the touch panel of the present invention is simple, which hardly increases the manufacturing costs. The touch display device includes the above touch panel, so that excellent display effects can be obtained.

Those skilled in the art will readily observe that numerous modifications and alterations of the device and method may be made while retaining the teachings of the invention.

What is claimed is:

1. A touch panel, comprising:
a substrate;
a plurality of sensing pads disposed on the substrate, two adjacent sensing pads being correspondingly disposed in parallel, and each of the sensing pad comprising:
a central part having a plurality of sides; and
a plurality of protrusion parts extending outwardly from each side of the central part;
wherein the plurality of protrusion parts disposed between each side of the two adjacent sensing pads are staggeredly arranged in sequence, and a gap between any two adjacent sensing pads in a normal direction is identical to each other.

2. The touch panel of claim 1, wherein the plurality of protrusion parts have the same shape.

3. The touch panel of claim 1, wherein each of the sensing pads further includes a plurality of indentation parts indenting inwardly from each side of the central part, and the plurality of protrusion parts and the plurality of indentation parts of each of the sensing pads are staggeredly arranged.

4. The touch panel of claim 3, wherein the plurality of protrusion parts and the plurality of indentation parts have the same shapes respectively.

5. The touch panel of claim 1, wherein the central part of each of the sensing pads is rhombus-shaped or square-shaped.

6. The touch panel of claim 1, wherein the plurality of protrusion parts of each of the sensing pads are rectangle-shaped, triangle-shaped, trapezoid-shaped or arc-shaped.

7. The touch panel of claim 1, wherein the gap between any two adjacent sensing pads is between 30 micrometers and 50 micrometers.

8. The touch panel of claim 1, wherein the plurality of protrusion parts of each of the sensing pads are identical in number.

9. The touch panel of claim 1, wherein the plurality of sensing pads comprise a transparent conductive material.

10. The touch panel of claim 9, wherein a material to form the transparent conductive material comprises indium tin oxide or indium zinc oxide.
